(19) United States
(12) Patent Application Publication
(10) Pub. No.: US 2023/0134994 A1
(43) Pub. Date: May 4, 2023

(54) SYSTEMS AND METHODS FOR NITRIDIZATION OF NIOBIUM TRACES

(71) Applicant: Raytheon Company, Waltham, MA (US)

(72) Inventor: Christopher Olson, Goleta, CA (US)

(73) Assignee: Raytheon Company, Waltham, MA (US)

(21) Appl. No.: 17/517,263

(22) Filed: Nov. 2, 2021

(51) Int. Cl. H01L 23/532; H01L 21/3205; H01L 21/285

(52) U.S. Cl. CPC H01L 23/53285; H01L 21/32058; H01L 21/2855

(57) ABSTRACT

A semiconductor device including an integrated circuit where the integrated circuit includes one or more layers forming electronic elements on a substrate of semiconductor material. A first layer includes a superconducting niobium trace connected to at least one of the electronic elements and a second layer includes superconducting niobium nitride positioned adjacent to a portion of the niobium trace.

### TECHNICAL FIELD

This application relates generally to semiconductor devices and, more particularly, to circuit traces for an integrated circuit of a semiconductor device, specifically superconducting circuit traces.

### BACKGROUND

An integrated circuit is a semiconductor device that has a substrate of a semiconductor material on which a series of layers are deposited using photolithographic techniques. The layers are doped, patterned and etched, so that electronic elements (e.g., resistances, capacitors, impedances, diodes, or transistors) are produced. Subsequently, other layers are deposited, which form the structure of interconnection layers necessary for electrical connections. The substrate may be made of a material such as Si, Ge, SiGe, GaAs, GaN or sapphire. The semiconductor device or chip may be made using technology such as metal-oxide-semiconductor field-effect transistor (MOSFET), bipolar or BiCMOS fabrication techniques. MOSFET technology may include complimentary metal-oxide-semiconductor (CMOS), P-channel metal-oxide-semiconductor (PMOS), N-channel metal-oxide-semiconductor (NMOS), UltraCMOS, silicon-on-insulator (SOI), or silicon-on-sapphire (SOS) variants.

Niobium (Nb) is a common Type II superconductor used for various superconducting applications. When one tries to build a typical semiconductor chip with thin Nb features, the Nb can be exposed to air, to liquids containing dissolved oxygen, or to high temperature oxidizing processes which cause it to oxidize to form Nb₂O₅, which is not a superconductor. This exposure alters or destroys the superconducting properties of the device. In addition, Nb transmission lines in a radio frequency (RF) device couple to each other. Hence, there is a need to reduce the penetration of external magnetic fields into an Nb wire or reduce the London Penetration Depth of the Nb wire or trace to reduce impedance caused by cross-talk or coupling and also to reduce variations in impedance based on process variability.

Niobium (Nb) is an excellent superconductor at low temperature (e.g., Tc ˜9K). But, Niobium oxide (e.g., NbOₓ, typically Nb₂O₅) is not a good superconductor. When superconducting devices are made using very thin Nb wires (e.g., sub-micron widths) via typical semiconductor processing, there is significant risk of oxidizing the surface of the Nb. This oxidation can happen in air (e.g., via native oxide formation), in cleaning chemistry, or in subsequent deposition processes. Depending on the thickness or diameter of the Nb wire and the depth of the oxidation, this can ruin the semiconductor device's superconducting properties and functionality. Hence, there is a need for more reliable and resilient applications of Nb traces in semiconductor devices.

### SUMMARY

The application, in various implementations, addresses deficiencies associated with existing Nb circuit traces in an integrated circuit of a semiconductor device. The application includes exemplary devices, systems and fabrication methods for providing Nb traces in a semiconductor device that are resistant to oxidation and other adverse effects.

This application describes exemplary techniques and devices that use Niobium Nitride (NbN) to protect an Nb trace in a semiconductor device. NbN is a higher temperature superconductor than Nb (e.g., 16K for NbN vs 9K for Nb). This, along with the idea of a NbN shell on the outside of the Nb traces protecting the Nb from oxidation during subsequent oxide processing, advantageously improves the performance of Nb trace superconducting devices.

Various implementations of the devices and methods described herein reduce variability of the superconducting properties of a Nb trace in a semiconductor chip by passivating the Nb trace with a self-limiting nitride that prevents oxidation of the Nb. In some implementations, the nitride formed on the surface of the Nb provides a superconductor that is superior to the Nb, resulting in a higher temperature superconducting shell and/or layer around the superconducting Nb and, thereby, resulting in superconducting properties arising in the trace starting at a higher temperature (such as 16K instead of 9K). In addition, the NbN shell around the outside of the Nb trace can reduce the London Penetration Depth and, thereby: reduce coupling between parallel Nb wires, reduce signal variability in the device, and reduce the need for ground wires to prevent coupling. Ultimately, such technical effects can result in smaller pitch semiconductor devices.

In one aspect, a semiconductor device includes an integrated circuit where the integrated circuit includes one or more layers forming electronic elements on a substrate of semiconductor material. The device also includes a first layer having a niobium trace connected to at least one of the electronic elements and a second layer having niobium nitride positioned adjacent to a portion of the niobium trace.

The second layer may be positioned above the first layer. The niobium nitride in the second layer may be formed via sputter deposition and/or a N₂-based gas forming process. The device may include a third layer having niobium nitride positioned adjacent to a portion of the niobium trace, where the third layer is positioned below the first layer. The niobium nitride in the second layer and in the third layer may be formed via sputter deposition and/or a N₂-based gas forming process. The niobium nitride may be positioned adjacent to a portion of the niobium trace within the first layer. In some implementations, the second layer is positioned below the first layer.

In another aspect, a semiconductor device includes an integrated circuit having one or more layers forming electronic elements on a substrate of semiconductor material and a first layer including a niobium nitride trace connected to at least one of the electronic elements.

In a further aspect, a method for manufacturing a semiconductor device having an integrated circuit includes: producing layers, in one or more stages, that form electronic elements on a semiconductor material substrate; forming a first layer including a niobium trace connected to at least one of the electronic elements; and forming a second layer including niobium nitride positioned adjacent to a portion of the niobium trace.

The method may include forming the second layer above the first layer. The forming of the niobium nitride in the second layer may be via sputter deposition and/or a N₂-based gas forming process. The method may include forming a third layer below the first layer including niobium nitride adjacent to a portion of the niobium trace. The method may include forming the niobium nitride in the second layer and in the third layer via sputter deposition and/or a N₂-based gas forming process. The method may include forming niobium nitride adjacent to a portion of the niobium trace within the first layer.

Any two or more of the features described in this specification, including in this summary section, may be combined to form implementations not specifically described in this specification.

The details of one or more implementations are set forth in the accompanying drawings and the following description. Other features and advantages will be apparent from the description and drawings, and from the claims.

### DESCRIPTION OF THE DRAWINGS

FIG. 1 is a view of a semiconductor device including an NbN shell surrounding portions of a Nb trace;

FIGS. 2A-2F are a series of views of the semiconductor device of FIG. 1 that show a portion of the semiconductor fabrication sequence including formation of a Nb trace and an NbN shell; and

FIG. 3 is a process for fabrication a semiconductor device including an Nb trace and NbN shell.

Like reference numerals in different figures indicate like elements.

### DETAILED DESCRIPTION

The application, in various aspects, addresses deficiencies associated with using Nb traces in an integrated circuit of a semiconductor device. The application includes exemplary devices including an NbN shell associated with an Nb trace and methods for fabrication of semiconductor devices including NbN shell and/or traces. In various implementations, device and techniques are implementations to encapsulate an Nb trace with Niobium Nitride (NbN), a stable, non-oxidizing superconductor.

The use of Niobium as a superconducting transmission line and/or trace is a very niche application. Most uses of Niobium in RF applications are for Superconducting RF (SRF) cavities. So, geometry and function are unique aspect of the implementations described herein. Utilizing a very narrow Niobium nitride trace as a thin superconducting trace in a semiconductor device is novel. Such SRF cavities, and generally most uses of Niobium, are less impacted by very thin layers of Niobium surface oxide. In addition, the processes used to treat such macro-cavities are very different from processes and/or devices describe herein that are used to treat a sub-micron width superconducting Nb wire and/or trace embedded in a silicon wafer. In addition, the device and methods described herein provide non-trivial technical solutions to prevent surface oxidation in a metal during semiconductor processing.

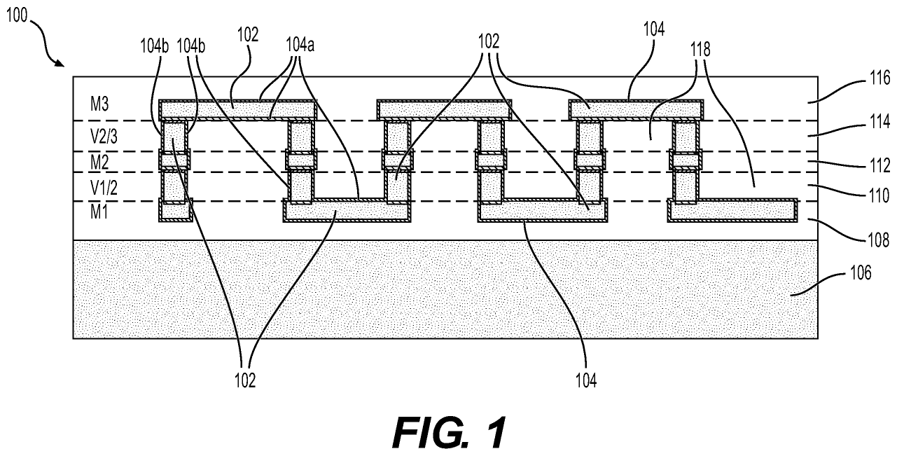

FIG. 1 is a view of a semiconductor device 100 including an NbN shell and/or layers 104 surrounding portions of one or more Nb traces 102. NbN shell 104 may include shell sections 104a deposited and/or oriented substantially on horizontal surfaces using, for example, sputter deposition and/or a N₂-based gas forming technique. NbN shell 104 may include shell sections 104b that may be formed and/or oriented along non-horizontal and/or vertical surfaces using, for example, a N₂-based gas forming technique. Device 100 may also include SiOₓ inter layer dielectric (ILD) 118 within one or more layers of device 100. At least one Nb trace 102 may be formed and/or positioned within a first layer of device 100. At least one NbN shell section 104a may be formed and/or positioned within a second layer of device 100 such that the NbN shell 104 is positioned adjacent to a portion of at least one of the Nb traces 102. Device 100 may include an integrated circuit having one or more layers forming electronic elements (not shown) on a substrate 106 of semiconductor material. The layers of device 100 may include, for example, M1 layer 108, V1/2 layers 110, M2 layer 112, V2/3 layers 114, and M3 layer 116. A first layer, e.g., layer 114, may include a niobium trace 102 connected to at least one electronic element, while a second layer, e.g., layer 116 may include niobium nitride, e.g., NbN shell 104 and/or NbN shell section 104a, positioned adjacent to a portion of the niobium trace 102. The niobium nitride may form a shell, cover, layer, passivation, and/or shield for the niobium trace 102. As shown in FIG. 1, layer 116, including NbN shell 104 having NbN shell section 104a, is positioned above and adjacent to layer 114 in the semiconductor stack of device 100.

The niobium nitride (NbₓN_{y} or NbN) shell, cover, passivation, layer, and/or shield 104 may be formed in any of the layers of device 100 including, for example, layers 108 and 116, via sputter deposition. One approach is to deposit NbN on top of Nb and/or Nb trace 102 during sputter deposition. This would prevent oxidation of the top surface of the Nb during patterning and etching. NbN can be deposited on the bottom of the Nb layer via sputter deposition. This would prevent oxidation of the bottom surface of the Nb and/or Nb trace 102 via diffusion of oxygen from adjacent layers during subsequent thermal processing such as annealing. FIG. 1, shows Nb transmission lines or traces 102 and stacked vias joining Nb transmission lines or traces 102 in different layers of device 100. The NbN shell 104 below the stack will prevent oxidation of the Nb caused by the underlying SiOₓ. The NbN shell 104 in between each Nb trace layer 102 will help prevent oxidation during processing (e.g., from wet chemistry or oxygen-containing environments). The NbN shell sections 104a on top of the Nb trace 102 will help prevent oxidation during patterning and/or from the SiOₓ layer deposited on top.

The NbN shell 104 in layers 108 and 116 may be formed via a N₂-based gas forming process. The process may also include H₂ or Ar and potentially a He catalyst to remove any pre-existing native oxides and maximize the stability of the resulting NbN passivation layer and/or shell 104. This method has the advantage of protecting the side walls of the Nb transmission lines and/or traces 102. While this is not highly critical for the primary stretch of the superconducting wire (represented as layers M1 and M3 in the FIG. 1), it is relevant for the stacked vias connecting the transmission lines and/or traces 102. These vias may be as narrow as 100 nm or less, and could easily fully oxidize during semiconductor processing, resulting in a non-superconducting portion of the superconducting transmission lines and/or traces 102. This method also has the advantage of replacing native oxide with nitride versus simply covering it up. NbN shell sections 104b may be configured as side walls arranged adjacent to and/or along the edges of each Nb trace 102.

As illustrated in FIG. 1, NbN shell 104 may be positioned adjacent to a portion of a Nb trace 102, where the NbN shell 104 is positioned in a layer above and/or below the layer including the Nb trace 102. For example, FIG. 1 shows NbN shell sections 104a in layers 108 and 116 that are positioned above and below Nb trace 102. NbN shell sections 104b may also be positioned adjacent to a portion of the Nb trace 102 within a semiconductor layer of device 100. For example, FIG. 1 shows NbN shell sections 104b extending vertically through V2/3 layer 114 on both sides of and adjacent to Nb trace 102.

In an alternate implementation, device 100 may use NbN traces instead of Nb traces with NbN shells to provide electrical connections for electronic elements. The fabrication process may include co-sputtered deposition of blanket NbN and subsequent patterning of NbN, and feature NbN rather than Nb as the primary superconducting transmission line. This method and/or implementation has a technical advantage of improved superconducting properties. NbN has a Tc of 16K versus a Tc of 9.7K for Nb. This method and/or implementation also has the potential to create highly pure NbN because the NbN is deposited from the start with no opportunity for oxidation of the Nb. With respect to FIG. 1, the Nb trace 102 can represent NbN traces, deposited via co-sputtering (or other means) from the beginning. In such an implementation, an NbN shell 104 may not be applied because trace 102 includes NbN instead of an Nb. There may be no pure Nb deposition in this implementation and/or process flow.

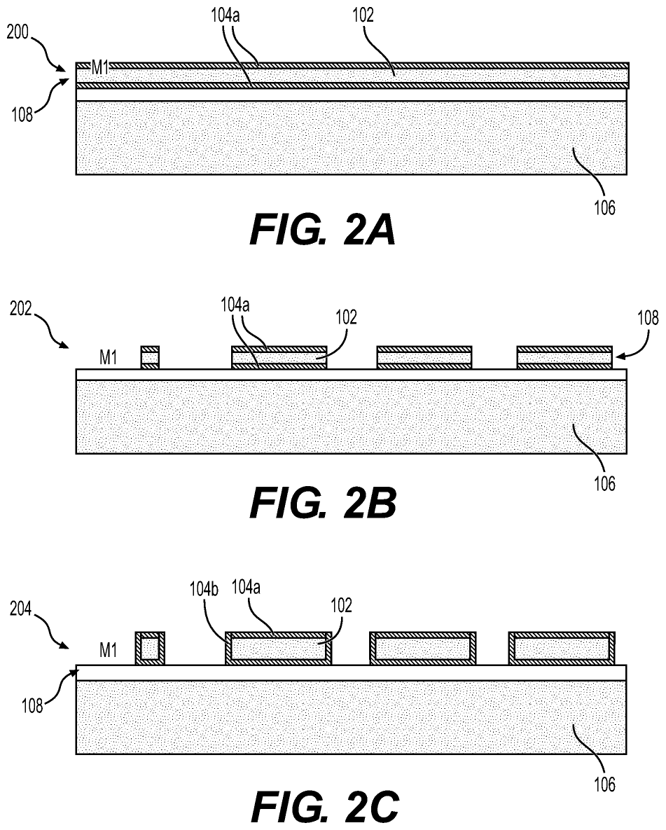

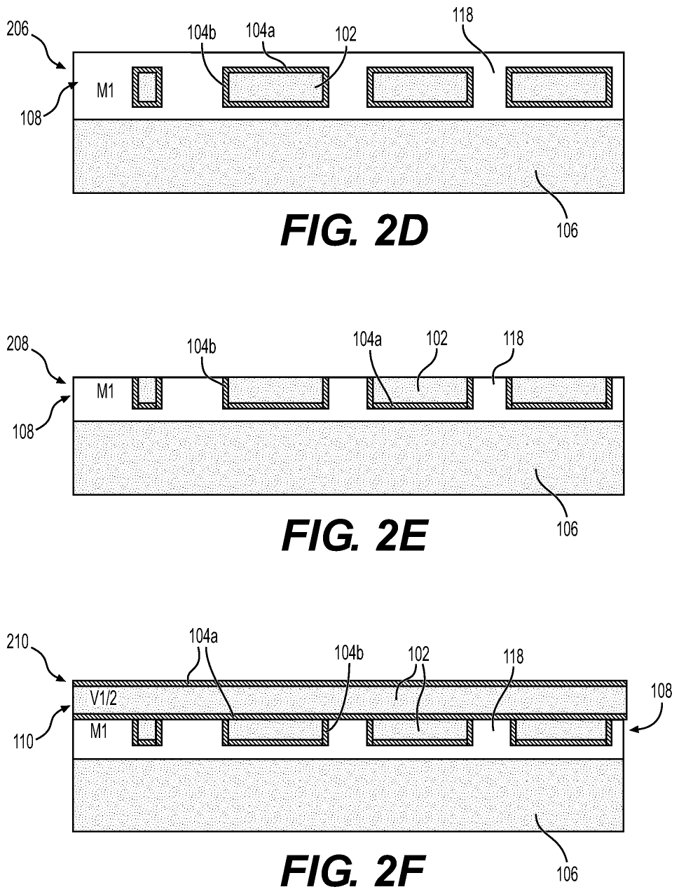

FIGS. 2A-2F include a series of views 200 through 210 of a semiconductor device such as device 100 of FIG. 1 that show a portion of a semiconductor fabrication sequence including formation of Nb traces 102 and NbN shell sections 104a.

FIG. 2A shows a view 200 of device 100 after a first process step including NbN deposition of a lower NbN shell section 104a using sputter deposition, Nb deposition of the Nb layer 102, and then sputter deposition of an upper NbN shell section 104a in M1 layer 108. FIG. 2B shows a view 202 of device 100 after a second process step including a pattern and etch process within M1 layer 108. FIG. 2C shows a view 204 of device 100 after a third process step including NbN deposition using plasma forming and/or N₂-based gas forming to nitridize the sidewalls in M1 layer 108 with NbN shells such as NbN shell section 104b. FIG. 2D shows a view 206 of device 100 after a further process step including SiOₓ ILD 118 deposition over M1 layer 108. FIG. 2E shows a view 208 of M1 layer 108 after a fifth process step including chemical-mechanical polishing (CMP) where a top portion of the SiOₓ ILD 118 and/or NbN shell section 104a (shown in FIG. 2D) has been removed. FIG. 2F shows a view 210 of device 100 after a sixth process step including two optional techniques including: 1) NbN deposition of a lower NbN shell section 104a using sputter deposition, Nb deposition of Nb layer 102, and then sputter deposition of an upper NbN shell section 104a in V1/2 layer 110 above M1 layer 108 where the sixth process step is essentially the same as the first process step but applied to forming nitridized Nb traces and/or posts in the V1/2 layer 110; or 2) performing gas plasma nitridization of the Nb surfaces exposed by CMP, and then putting down the next metal layer 110.

The first through fifth process steps may be repeated to form any number of traces, posts, vias, or other elements including Nb 102 surrounded by NbN 104 shells in any number of layers of device 100. Various deposition techniques may be used as known to one of ordinary skill such as, without limitation, atomic layer deposition (ALD), plasma enhanced ALD, physical vapor deposition (PVD), chemical vapor deposition (CVD), plasma enhanced chemical vapor deposition (PECVD), and the like.

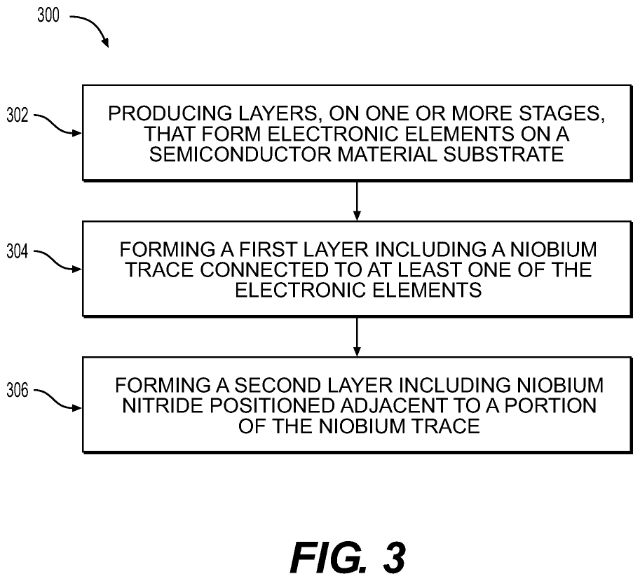

FIG. 3 is a process 300 for fabrication a semiconductor device including an Nb trace and NbN such as device 100. Process 300 includes: producing layers, in one or more stages, that form electronic elements on a semiconductor material substrate 106 (Step 302); forming a first layer including a niobium trace 102 connected to at least one of the electronic elements (Step 102); and forming a second layer including niobium nitride, e.g., NbN shell 104, positioned adjacent to a portion of the niobium trace 102.

Elements or steps of different implementations described may be combined to form other implementations not specifically set forth previously. Elements or steps may be left out of the systems or processes described previously without adversely affecting their operation or the operation of the system in general. Furthermore, various separate elements or steps may be combined into one or more individual elements or steps to perform the functions described in this specification.

Other implementations not specifically described in this specification are also within the scope of the following claims.

What is claimed is:

1. A semiconductor device including an integrated circuit, the integrated circuit comprising:
one or more layers forming electronic elements on a substrate of semiconductor material,
a first layer including a niobium trace connected to at least one of the electronic elements; and
a second layer including niobium nitride positioned adjacent to a portion of the niobium trace.

2. The device of claim 1, wherein the second layer is positioned above the first layer.

3. The device of claim 2, wherein the niobium nitride in the second layer is formed via sputter deposition.

4. The device of claim 2, wherein the niobium nitride in the second layer is formed via a N₂-based gas forming process.

5. The device of claim 2 comprising a third layer including niobium nitride positioned adjacent to a portion of the niobium trace, wherein the third layer is positioned below the first layer.

6. The device of claim 5, wherein the niobium nitride in the second layer and in the third layer is formed via at least one of sputter deposition and a N₂-based gas forming process.

7. The device of claim 1, wherein niobium nitride is positioned adjacent to a portion of the niobium trace within the first layer.

8. The device of claim 7, wherein the niobium nitride in the first layer is formed via an N₂-based gas forming process.

10. The device of claim 1, wherein the second layer is positioned below the first layer.

11. The device of claim 10, wherein the niobium nitride is formed in the second layer via at least one of spluttering deposition and a N₂-based gas forming process.

12. A semiconductor device including an integrated circuit, the integrated circuit comprising:
one or more layers forming electronic elements on a substrate of semiconductor material, and
a first layer including a niobium nitride trace connected to at least one of the electronic elements.

13. A method for manufacturing a semiconductor device including an integrated circuit comprising:
producing layers, in one or more stages, that form electronic elements on a semiconductor material substrate;
forming a first layer including a niobium trace connected to at least one of the electronic elements; and
forming a second layer including niobium nitride positioned adjacent to a portion of the niobium trace.

14. The method of claim 13 comprising forming the second layer above the first layer.

15. The method of claim 14 comprising forming the niobium nitride in the second layer via sputter deposition.

16. The method of claim 14 comprising forming the niobium nitride in the second layer via a N₂-based gas forming process.

17. The method of claim 14 comprising forming a third layer below the first layer including niobium nitride adjacent to a portion of the niobium trace.

18. The method of claim 17 comprising forming the niobium nitride in the second layer and in the third layer via at least one of sputter deposition and a N₂-based gas forming process.

19. The method of claim 13 comprising forming niobium nitride adjacent to a portion of the niobium trace within the first layer.

20. The method of claim 19 comprising forming the niobium nitride in the first layer via a N₂-based gas forming process.
